(19) United States
(12) Patent Application Publication
(10) Pub. No.: US 2026/0033360 A1
(43) Pub. Date: Jan. 29, 2026

(54) Power Module

(71) Applicants: HYUNDAI MOTOR COMPANY, Seoul (KR); KIA CORPORATION, Seoul (KR)

(72) Inventors: Han Jin Do, Hwaseong-si (KR); Jin Myeong Yang, Hwaseong-si (KR); Sung Won Park, Hwaseong-si (KR)

(73) Assignees: HYUNDAI MOTOR COMPANY, Seoul (KR); KIA CORPORATION, Seoul (KR)

(21) Appl. No.: 18/967,568

(22) Filed: Dec. 3, 2024

(30) Foreign Application Priority Data
Jul. 24, 2024 (KR) 10-2024-0098208

(51) Int. Cl. H01L 23/498

(52) U.S. Cl. CPC H01L 23/49838; H01L 23/49811; H01L 23/49833; H01L 23/49861

(57) ABSTRACT

In the present disclosure, a central substrate is additionally disposed between an upper and lower substrates, thereby simplifying a current loop of a module. In addition, by simplifying the current loop between the upper and lower substrates, the central substrate enhances current overlap effect. Further disclosed is a power module in which an insulating pattern and a via spacer to form the current loop are reduced in size, resulting in a reduction of the overall module size.

### CROSS-REFERENCE TO RELATED APPLICATION(S)

This application is based on and claims priority under 35 U.S.C. 119 to Korean Patent Application No. 10-2024-0098208, filed on Jul. 24, 2024, in the Korean Intellectual Property Office, the disclosure of which is herein incorporated by reference in its entirety.

### TECHNICAL FIELD

The present disclosure relates to a power module in which a central substrate is placed between an upper substrate and a lower substrate to improve operating efficiency.

### BACKGROUND

Recently, as interest in the environment has increased, eco-friendly vehicles that use electric motors as their power source are increasing. Eco-friendly vehicles are also referred to as electrified vehicles, and representative examples include electric vehicles (EVs) and hybrid electric vehicles (HEVs).

These electrified vehicles are equipped with an inverter to convert direct current into alternating current during motor operation, and the inverter may include one or more power modules incorporating semiconductor chips that perform switching functions.

Meanwhile, during the operation of the power modules, the semiconductor chips generate heat due to high voltage and high current. Therefore, when the temperature of the power module increases due to the heat generated from the semiconductor chips, the operation of the power module will be affected. Thus, heat dissipation ensures stable operation of the power module.

Accordingly, various cooling methods are applied to dissipate the heat generated by power modules. For example, a cooling channel is connected to a substrate and refrigerant is circulated through the cooling channel to enhance cooling efficiency through heat exchange between the refrigerant and the substrate.

The methods of connecting such a cooling channel may be divided into indirect and direct cooling methods.

First, the indirect cooling method is a method in which a material such as thermal interface material (TIM) is inserted between a substrate and a cooling channel, allowing heat to be transferred from the substrate to the cooling channel via the material.

The direct cooling method is a method in which heat transfer occurs while a substrate is directly coupled to a cooling channel.

In addition, the direct cooling method of the power module may be divided into a single-sided cooling method in which heat generated from a semiconductor chip is transferred to one substrate for cooling, and a double-sided cooling method in which heat is distributed and transferred to upper and lower substrates for cooling.

With double-sided cooling power modules, the size and electrical characteristics of the module greatly affect reliability. Thus, smaller modules with better electrical characteristics offer improved reliability.

Meanwhile, as the output requirements for inverters continue to rise, the heat generated by semiconductor chips is also increasing to support higher output. To handle the increased heat generation, the sizes of components such as semiconductor chips and substrates are also being increased.

As the sizes of modules increase, the current loops become longer and more complex, which may lead to a deterioration in the electrical characteristics of the modules or cause warping of substrates, causing reliability issues. Therefore, solutions should be presented to address these problems.

The foregoing described as the background art is intended merely to aid in the understanding of the background of the present disclosure, and is not intended to mean that the present disclosure falls within the purview of the related art already known to those skilled in the art.

### SUMMARY

In view of the foregoing, the present disclosure provides a power module in which operating efficiency is enhanced by adding a central substrate between upper and lower substrates.

A power module according to the present disclosure may include an upper substrate and a lower substrate vertically spaced apart from each other, and a central substrate disposed between the upper substrate and the lower substrate. The central substrate may include multiple conductive parts configured to electrically connect the upper substrate and the lower substrate, and an insulating part configured to insulate each of the conductive parts. The multiple conductive parts may include a first conductive part electrically connected to one of the upper substrate and the lower substrate, a second conductive part electrically connecting the upper substrate and the lower substrate, and a third conductive part electrically connected to a signal lead.

The power module may further include a semiconductor chip disposed on the lower substrate, and at least one of the first conductive part and the second conductive part is connected to the semiconductor chip.

The first conductive part may extend in a planar shape to form a current path in a horizontal direction.

The first conductive part may include a metal material in a planar shape extending in a horizontal direction to form a current path across its (e.g., entire) area.

The second conductive part may be partitioned from the first conductive part by an insulating part, and extend in a vertical direction to be electrically connected to the upper substrate and the lower substrate.

The first conductive part may have a planar shape, the second conductive part may be disposed on an area of the first conductive part and form a same plane as the first conductive part, and a periphery of the second conductive part may be insulated from the first conductive part by the insulating part.

The third conductive part may form a pattern on the insulating part, thereby being electrically blocked from other conductive parts and forming a signal lead.

The first conductive part may have a planar shape, the insulating part may be coated on one surface of the first conductive part, and the third conductive part may form a pattern on an exposed surface of the insulating part.

A spacer may be coupled to the second conductive part, and the upper substrate and the lower substrate may be electrically connected through the second conductive part and the spacer.

The spacer may include an upper spacer and a lower spacer, in which the upper spacer is electrically connected to the upper substrate and the second conductive part, and the lower spacer is electrically connected to the lower substrate and the second conductive part.

A through hole may be formed in the first conductive part, and the second conductive part may have a vertically extending shape and electrically connects the upper substrate and the lower substrate by penetrating the through hole.

A power lead may be connected to at least one of the upper substrate and the lower substrate, and a lead connector may extend in the central substrate in a direction where the power lead is provided.

The lead connector may include or be connected to one of a positive terminal, a negative terminal, and an output terminal, and the power lead may include one of two remaining terminals.

The lead connector may be spaced apart from the power lead to vertically overlap the power lead.

The first conductive part may be in the form of a flat plate, and the current path in the first conductive part may be formed to vertically overlap the current path in the upper or lower substrate.

In a power module configured as described above, since a central substrate is additionally disposed between the upper and lower substrates, a current loop of the module is simplified.

In addition, by simplifying the current loop between the upper and lower substrates, the central substrate enhances current overlap effect.

Furthermore, an insulating pattern and a via spacer for forming a current loop are reduced in size, resulting in a reduction of the overall module size.

### BRIEF DESCRIPTION OF THE DRAWINGS

The above and other aspects, features, and advantages of the present disclosure will be more apparent from the following detailed description taken in conjunction with the accompanying drawings, in which:

FIG. 1 is a view illustrating a power module according to an embodiment of the present disclosure;

FIG. 2 is a view illustrating a central board of the power module illustrated in FIG. 1;

FIG. 3 is a top view of the central board according to an embodiment of the present disclosure;

FIG. 4 is a bottom view of the central board according to an embodiment of the present disclosure;

FIG. 5 is a view illustrating a power module according to another embodiment of the present disclosure;

FIG. 6 is a top view of a lower board of the power module according to another embodiment of the present disclosure;

FIG. 7 is a view illustrating a power module according to still another embodiment of the present disclosure;

FIG. 8 is a view illustrating a power module according to still another embodiment of the present disclosure;

FIG. 9 is a view illustrating a central board of the power module according to the embodiment illustrated in FIG. 8;

FIG. 10 is a top view illustrating the central board according to the embodiment illustrated in FIG. 8;

FIG. 11 is a bottom view illustrating the central board according to the embodiment illustrated in FIG. 8; and

FIG. 12 is a view illustrating a power module according to yet another embodiment of the present disclosure.

### DETAILED DESCRIPTION

A specific structural or functional description of embodiments of the disclosure set forth in the present specification or application is given merely for the purpose of describing the embodiment according to the present disclosure. Therefore, the embodiments according to the present disclosure may be implemented in various forms, and the present disclosure should not be construed as being limited to the embodiments described in the specification or application.

Various changes and modifications may be made to the embodiments according to the present disclosure, and therefore particular embodiments will be illustrated in the drawings and described in the specification or application. However, it should be understood that embodiments according to the concept of the present disclosure are not limited to the particular disclosed embodiments, but the present disclosure includes all modifications, equivalents, and alternatives falling within the spirit and scope of the present disclosure.

Unless defined otherwise, all terms used herein, including technical and scientific terms, have the same meaning as those commonly understood by a person skilled in the art to which the present disclosure pertains. Such terms as those defined in a generally used dictionary may be interpreted to have the meanings equal to the contextual meanings in the relevant field of art, and are not to be interpreted to have ideal or excessively formal meanings unless clearly defined in the present disclosure.

Hereinafter, embodiments set forth herein will be described in detail with reference to the accompanying drawings, and the same or similar elements are given the same and similar reference numerals regardless of figure numbers, so duplicate descriptions thereof will be omitted.

The terms “module” and “unit” used for the elements in the following description are given or interchangeably used in consideration of the ease of writing the specification, and do not have distinct meanings or roles by themselves.

In describing the embodiments set forth herein, a detailed description of known functions or configurations incorporated herein will be omitted when it is determined that the description may make the subject matter of the embodiments set forth herein unclear. In addition, it should be appreciated that the accompanying drawings are provided for the sake of easy understanding of the embodiments set forth herein, and the technical idea of the present disclosure is not limited to the accompanying drawings and includes all modifications, equivalents, or alternatives falling within the spirit and scope of the present disclosure.

Terms including an ordinal number such as “a first” and “a second” may be used to describe various elements, but the elements are not limited to the terms. The above terms are used merely for the purpose of distinguishing one element from other elements.

In the case where an element is referred to as being “connected” or “coupled” to any other elements, it should be understood that not only the element may be directly connected or coupled to the other elements, but also another element may exist therebetween. Contrarily, in the case where an element is referred to as being “directly connected” or “directly coupled” to any other element, it should be understood that no other element exists therebetween.

A singular expression may include a plural expression unless they are definitely different in a context.

As used herein, the expression “include” or “have” are intended to specify the existence of mentioned features, numbers, steps, operations, elements, components, or combinations thereof, and should be construed as not precluding the possible existence or addition of one or more other features, numbers, steps, operations, elements, components, or combinations thereof.

In an embodiment of the present disclosure, a central substrate 300 is used to form a current path in a direction that intersects with the vertical current path directions formed by an upper substrate 100 and a lower substrate 200, with the aim of simplifying the current loop and increasing the current overlap.

Here, the current loop may be defined as a path through which the current, input from an external source, passes through each component inside a power module and is then output back to the exterior. The current loop may be configured through a combination of current paths formed by each component of the power module.

The current overlap may increase as the current loop becomes narrower, and as the degree of overlap increases, the operating efficiency of the power module may be improved due to mutual induction.

In this disclosure, expressions such as upper and lower directions, including the upper substrate 100 and lower substrate 200, are used to represent the relationship between the components for the convenience of understanding and do not imply (e.g., absolute) directionality.

Hereinafter, a power module according to an embodiment of the present disclosure will be described with reference to the accompanying drawings.

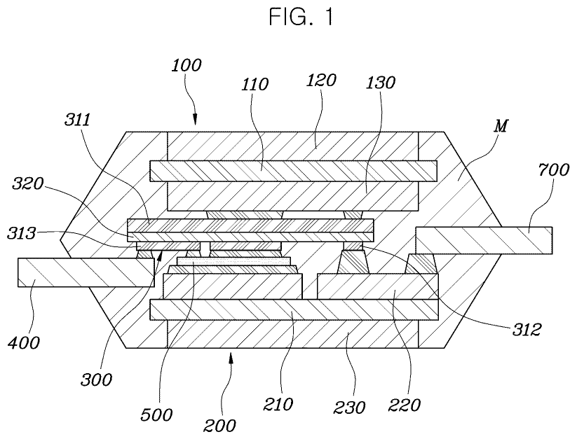

As illustrated in FIGS. 1 to 4, a power module includes an upper substrate 100 and a lower substrate 200 vertically spaced apart from each other, and a central substrate 300 disposed between the upper substrate 100 and lower substrate 200. The central substrate includes multiple conductive parts for electrically connecting the upper substrate 100 and the lower substrate 200, and an insulating part 320 that insulates respective conductive parts. The multiple conductive parts include a first conductive part 311 electrically connected to one of the upper substrate 100 and the lower substrate 200, a second conductive part 312 electrically connecting the upper substrate 100 and the lower substrate 200, and a third conductive part 313 electrically connected to a signal lead 400.

In FIG. 1, the components related to the present disclosure are mainly illustrated, and the actual power module may be implemented with more or fewer components than this.

The upper substrate 100, the lower substrate 200, and the central substrate 300 may be configured by being molded in a mold part M.

The upper substrate 100 may include a first insulating layer 110, and a first metal layer 120 and a second metal layer 130, which are disposed on the top and bottom surfaces of the first insulating layer 110, respectively.

The lower substrate 200 may be spaced apart from the bottom side of the upper substrate 100, and may include a second insulating layer 210, and a third metal layer 220 and a fourth metal layer 230, which are disposed on the top and bottom surfaces of the second insulating layer 210, respectively.

Accordingly, the second metal layer 130 of the upper substrate 100 and the third metal layer 220 of the lower substrate 200 are disposed to face each other. In the present disclosure, a semiconductor chip 500 may be disposed on the lower substrate 200. Alternatively, the semiconductor chip 500 may be disposed on the upper substrate 100.

The first insulating layer 110 and the second insulating layer 210 enable the interior and exterior of the power module to be electrically isolated, while heat generated by the semiconductor chip 500 may be transferred to the second metal layer 130 and the third metal layer 220 disposed inside the module. In addition, the first metal layer 120 may re-transfer the heat received from the second metal layer 130, and the fourth metal layer 230 may re-transfer the heat received from the third metal layer.

That is, the first metal layer 120 and the fourth metal layer 230 discharge the heat, received through heat exchange with the exterior, to the exterior and perform the role of cooling the power module, thereby lowering the operating temperature of the power module and allowing the power module to operate stably.

In addition, in order to improve the cooling performance of the power module, a cooling channel may be additionally provided outside the first metal layer 120 or the fourth metal layer 230. The cooling channel may be applied as, for example, an air-cooled or water-cooled type, and may enhance the cooling performance of the power module by enhancing the cooling efficiency by refrigerant.

Meanwhile, the first to fourth metal layers 120, 130, 220, and 230 may be made of, for example, copper (Cu), and the first insulating layer 110 and the second insulating layer 210 may be made of ceramic. In this case, the upper substrate 100 and the lower substrate 200 may be implemented as an active metal brazed (AMB) substrate or a direct bonded copper (DBC) substrate.

Meanwhile, a power lead 700 may be connected to at least one of the upper substrate 100 and the lower substrate 200. The power lead 700 is responsible for current input and output in relation to the exterior, and may correspond to either the negative terminal N, positive terminal P, and output terminal O.

Meanwhile, a semiconductor chip 500 may be disposed on the lower substrate 200. Multiple semiconductor chips 500 may be provided, and are not restricted to being disposed on the lower substrate 200. The semiconductor chips 500 may also be disposed on the upper substrate 100 and may be placed in a flipped state.

The semiconductor chips 500 may be switched on/off in response to a switching signal, and whether current is transmitted between the upper and lower portions may be determined depending on the switching operation of the semiconductor chips 500.

Here, the switching signal may be input in the form of voltage through a signal pad provided in the semiconductor chip 500. When a switching signal is input, at least one semiconductor chip 500 is electrically connected so that current can flow to a power pad provided together with the switching pad.

The semiconductor chip 500 may be, for example, a switching element such as an insulated gate bipolar transistor (IGBT) or a metal-oxide-semiconductor field-effect transistor (MOSFET). In addition, silicon (Si) or silicon carbide (SiC) may be applied as the material of the semiconductor chip 500.

In the present disclosure, the central substrate 300 is provided between the upper substrate 100 and the lower substrate 200, so that a current path can be formed in a direction intersecting with the direction of the current path between the upper substrate 100 and the lower substrate 200.

The central substrate 300 may include multiple conductive parts and an insulating part 320, and the conductive parts may be made of a metal material through which current can flow, and the insulating part 320 may be molded and bonded so that the multiple conductive parts can be insulated.

The conductive parts may be divided into a first conductive part 311, a second conductive part 312, and a third conductive part 313.

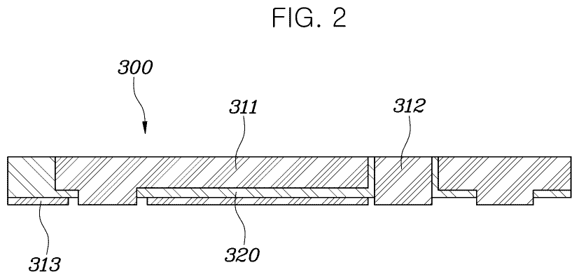

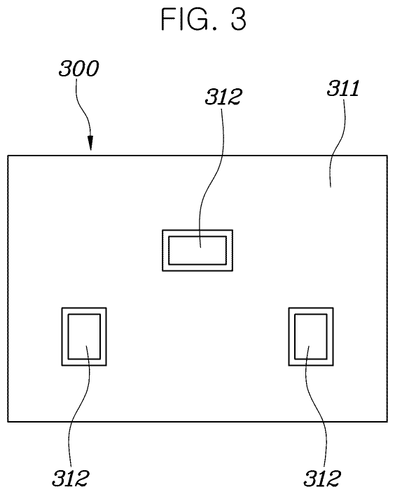

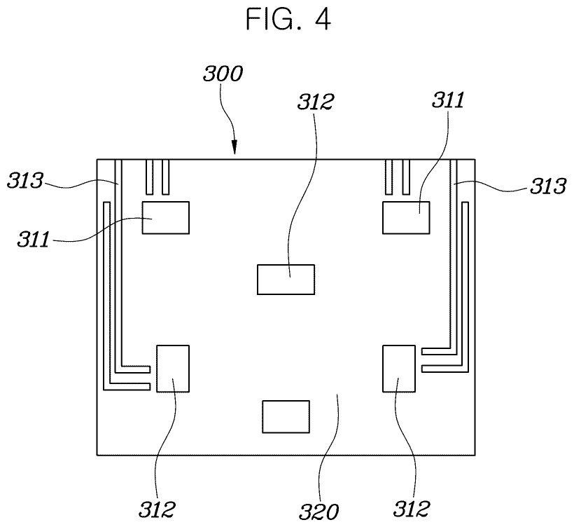

Regarding this, referring to figures, FIG. 2 is a vertical cross-sectional view of the central substrate 300 according to an embodiment, FIG. 3 is a top view of the central substrate 300 according to an embodiment, and FIG. 4 is a bottom view of the central substrate 300 according to an embodiment.

The first conductive part 311 is electrically connected to one of the upper substrate 100 and the lower substrate 200 to form a current path with the upper substrate 100 or the lower substrate 200. According to an embodiment of the present disclosure, the first conductive part 311 is electrically connected to the lower substrate 200.

The first conductive part 311 may extend in a plane to form a current path in a horizontal direction. That is, the first conductive part 311 may be made of a metal material in a horizontally extending flat shape and may form a current path across its (e.g., entire) area.

In this way, the first conductive part 311 may extend in a plane to have a surface facing the upper substrate 100 or the lower substrate 200, and may be formed of a metal layer of the same material as the second metal layer 130 of the upper substrate 100 and the third metal layer 220 of the lower substrate 200 to enable electrical connection therebetween.

In addition, the first conductive part 311 may form a current path across the (e.g., entire) surface, and may configure the current path in various ways through the partition of a pattern or area. Here, the horizontal direction refers to a direction intersecting the current connection direction of the upper substrate 100 and the lower substrate 200, and may be an extension direction on the surface provided as the first conductive part 311 is formed in the planar shape.

The second conductive part 312 electrically connects the upper substrate 100 and the lower substrate 200. That is, the second conductive part 312 passes through the central substrate 300 to electrically connect the upper substrate 100 and the lower substrate 200.

The second conductive part 312 is partitioned from the first conductive part 311 by an insulating part 320 and extends in the vertical direction to electrically connect the upper substrate 100 and the lower substrate 200. For this purpose, the second conductive part 312 may be made of a material that allows current flow, and may also be configured as a spacer 600.

Specifically, the first conductive part 311 may have a planar shape, the second conductive part 312 may be disposed on an area of the first conductive part 311 and form the same plane as the first conductive part 311, and the periphery of the second conductive part 312 may be insulated from the first conductive part 311 by the insulating part 320.

That is, the first conductive part 311 may be formed in a planar shape, and the second conductive part 312 is disposed through a portion of the first conductive part 311, but its edge is insulated by the insulating part 320. Thus, the first conductive part 311 and the second conductive part 312 are not electrically connected to each other.

Due to this, the first conductive part 311 may form a current path in the horizontal direction according to the planar shape, and the second conductive part 312 may form a current path in the vertical direction by extending in the vertical direction and being connected to the upper substrate 100 and the lower substrate 200. In addition, the first conductive part 311 and the second conductive part 312 are insulated by the insulating part 320 to form different current paths.

At least one of the first conductive part 311 and the second conductive part 312 described above may be connected to the semiconductor chip 500.

Meanwhile, the third conductive part 313 is electrically connected to the signal lead 400 to enable signal input including switching of the semiconductor chip 500. The third conductive part 313 may be configured to be insulated from the first conductive part 311 and the second conductive part 312 by the insulating part 320, and the signal lead 400 is connected to form a current path.

In particular, the third conductive part 313 may form a pattern in the insulating part 320 so that the electrical connection with other conductive parts can be (e.g., substantially) blocked, and may configure the signal lead 400.

As an example, the first conductive part 311 may have a planar shape, the insulating part 320 may be coated on one side of the first conductive part 311, and the third conductive part 313 may be provided to form a pattern on the exposed surface of the insulating part 320. In this way, the third conductive part 313 may be formed in a pattern on the insulating part 320 to be insulated from the first conductive part 311 and the second conductive part 312 while allowing the signal lead 400 capable of signal input to be connected to the third conductive part. In this way, in the present disclosure, since the central substrate 300 is provided with the signal lead 400, a separate wire for connecting the signal lead 400 may be removed, thereby reducing the overall size of the power module and narrowing the current loop.

In this way, the central substrate 300 may be connected to at least one of the upper substrate 100, the lower substrate 200, and the signal lead 400 through the first conductive part 311, the second conductive part 312, and the third conductive part 313 to form a current flow.

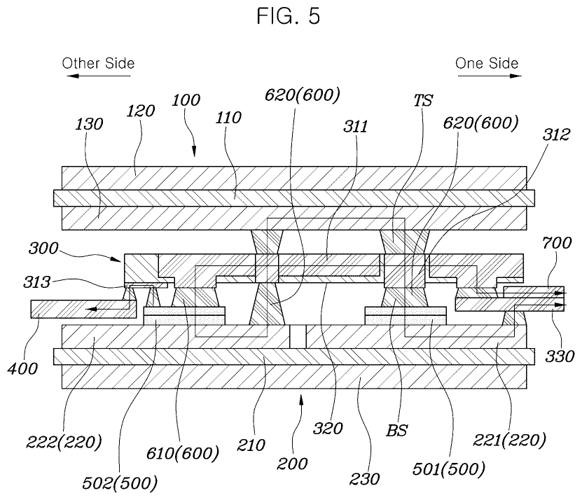

The present disclosure can be applied in various embodiments depending on the number of semiconductor chips 500 and current paths of semiconductor chips 500. As another embodiment, as illustrated in FIG. 5, multiple semiconductor chips 500 may be provided and electrically connected to the upper substrate 100 and the lower substrate 200 through multiple conductive parts provided on the central substrate 300 to form current paths.

Meanwhile, the present disclosure may be applied in various embodiments in which the central substrate 300 is electrically connected to the upper substrate 100 and the lower substrate 200.

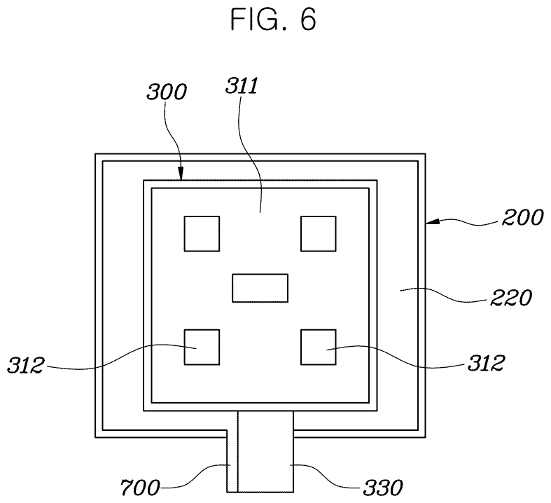

In FIGS. 5 and 6, as an example, multiple semiconductor chips 500 are provided, and accordingly, the third metal layer 220 of the lower substrate 200 is partitioned for each semiconductor chip 500.

As an example, as illustrated in FIG. 5, spacers 600 are coupled to the second conductive part 312, so that the upper substrate 100 and the lower substrate 200 can be electrically connected through the second conductive part 312 and the spacers 600.

That is, the central substrate 300 may be electrically connected to the upper substrate 100 and the lower substrate 200 via the spacers 600.

Referring to FIG. 5, the first conductive part 311 of the central substrate 300 may be electrically connected to the semiconductor chips 500 of the lower substrate 200 via first spacers 610, and the second conductive part 312 may be electrically connected to the upper substrate 100 and the lower substrate 200 via second spacers 620. Here, the second spacers 600 may each include an upper spacer TS and a lower spacer BS, in which the upper spacer TS may be electrically connected to the upper substrate 100 and the second conductive part 312, and the lower spacer BS may be electrically connected to the lower substrate 200 and the second conductive part 312.

Through this, the central substrate 300 may form a current path in the horizontal direction via the first conductive part 311 as the first conductive part is electrically connected to the lower substrate 200, and may form a current path in the vertical direction via the second conductive part 312 as the second conductive part is connected to the upper substrate 100 and the lower substrate 200.

In addition, the third conductive part 313 may be directly connected to the signal lead 400 to receive a signal.

In FIG. 5, arrows represent the flow of current, and, through the central substrate 300, a current loop may be formed in which current flows in the order of power lead 700—one side third metal layer 221 of lower substrate 200—one side semiconductor chip 501—one side second spacer 620—second metal layer 130 of upper substrate 100—the other side second spacer 620—the other side third metal layer 222 of lower substrate 200—the other side semiconductor chip 502—the other side first spacer 610—central substrate 300 or in the reverse order.

In this way, through the current path formed by the central substrate 300, the current no longer moves repeatedly through each spacer 600 allowing the current loop to be simplified.

In addition, as illustrated in FIG. 6, the first conductive part 311 in the form of a flat plate, and the current path in the first conductive part 311 may be formed to overlap the current path in the upper substrate 100 or the lower substrate 200 in the vertical direction. As a result, as the current loop becomes narrower, the current overlap is enhanced, allowing almost the (e.g., entire) area of the central substrate 300 on the plane to fall within the high current overlap area. As the high current overlap area expands in this way, the operating efficiency of the power module can be improved.

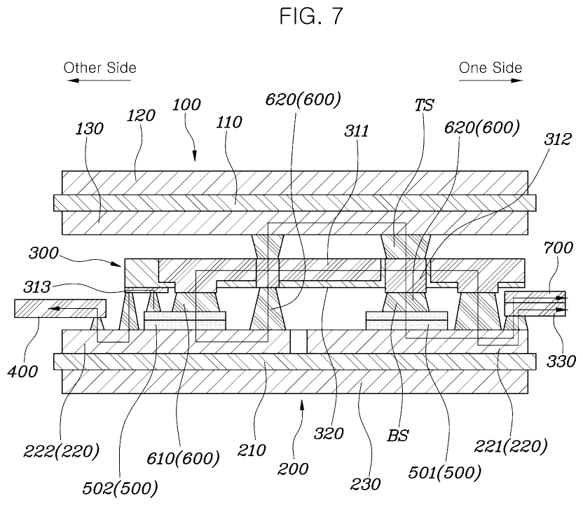

Meanwhile, as illustrated in FIG. 7, the third conductive part 313 may be configured to be electrically connected to the signal lead 400 via the lower substrate 200. To this end, a pattern may be formed on the third metal layer 220 of the lower substrate 200, the signal lead 400 may be connected to the third metal layer 220 of the lower substrate 200, and the third conductive part 313 may be configured to be connected to the signal lead 400 in the third metal layer 220 of the lower substrate 200. The connection structure of the signal lead 400 may be selectively applied depending on the size and specifications of the power module.

As another embodiment, a through hole H may be formed in the first conductive part 311, and the second conductive part 312 may have a shape extending in the vertical direction to electrically connect the upper substrate 100 and the lower substrate 200 by penetrating the through hole H.

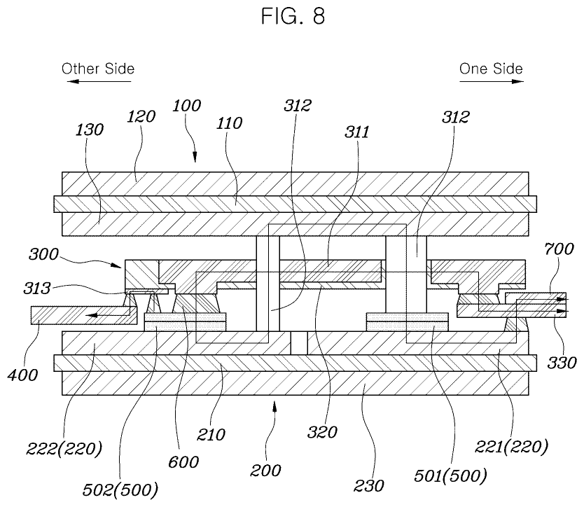

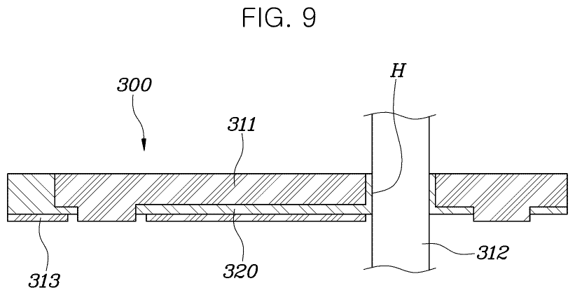

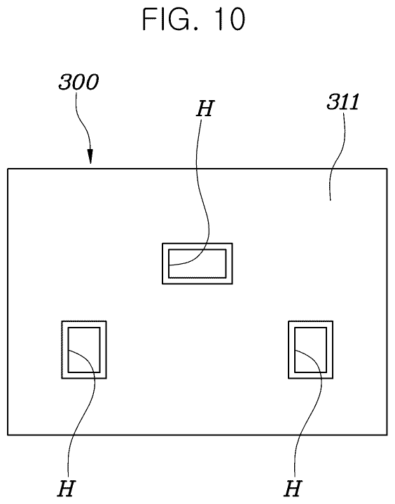

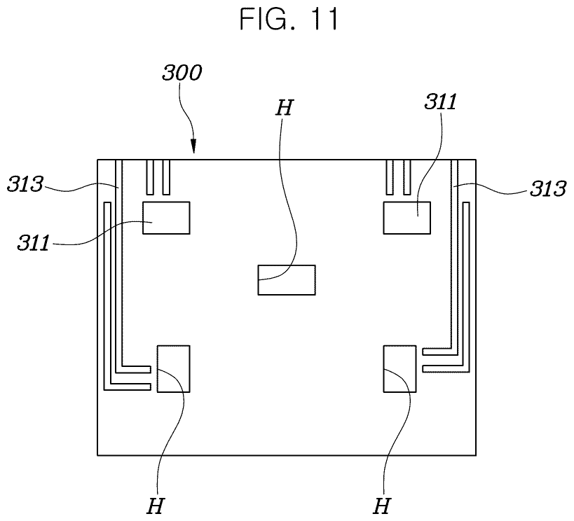

As illustrated in FIGS. 8 to 11, the through hole H may be formed in the first conductive part 311, and the second conductive part 312 may extend to pass through the through hole H and be connected to the upper substrate 100 and the lower substrate 200.

That is, the first conductive part 311 may be connected to either the upper substrate 100 or the lower substrate 200 via a spacer 600 or a connector made of, for example, copper, and the through hole H may be formed in a portion of the first conductive part 311, allowing the second conductive part 312 to pass through the through hole H and be connected to the upper substrate 100 and the lower substrate 200.

Through this, the central substrate 300 may form a current path in the horizontal direction via the first conductive part 311 as the first conductive part 311 is electrically connected to the lower substrate 200, and may form a current path in the vertical direction via the second conductive part 312 as the second conductive part 312 passes through the through hole H in the first conductive part 311 and is connected to the upper substrate 100 and the lower substrate 200.

The third conductive part 313 may be directly connected to the signal lead 400 to receive a signal.

In FIG. 8, arrows represent the flow of current, and, through the central substrate 300, a current loop may be formed in which current flows in the order of power lead 700—one side third metal layer 221 of lower substrate 200—one side semiconductor chip 501—one side second conductor 312—second metal layer 130 of upper substrate 100—the other side second conductor 312—the other side third metal layer 222 of lower substrate 200—the other side semiconductor chip 502—central substrate 300 or in the reverse order.

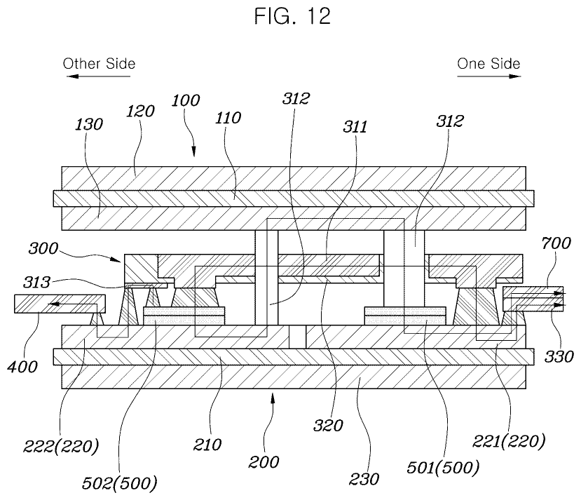

Meanwhile, as illustrated in FIG. 12, the third conductive part 313 may be configured to be electrically connected to the signal lead 400 via the lower substrate 200. To this end, a pattern may be formed on the third metal layer 220 of the lower substrate 200, the signal lead 400 may be connected to the third metal layer 220 of the lower substrate 200, and the third conductive part 313 may be configured to be connected to the signal lead 400 in the third metal layer 220 of the lower substrate 200. The connection structure of the signal lead 400 may be selectively applied depending on the size and specifications of the power module.

In the present disclosure, the signal lead 400 is described with respect to an embodiment configured to be electrically connected to the third conductive part 313, and if the signal lead 400 is configured separately, the third conductive part 313 may be omitted.

Meanwhile, on the central substrate 300, a lead connector 330 may extend in the direction where a power lead 700 is provided.

Referring to FIGS. 5 and 6, the lead connector 330 may extend from the central substrate 300 and be configured to allow current to be input and output. This lead connector 330 may include or be connected to one a positive terminal, a negative terminal, and an output terminal. In this case, the power lead 700 may include one of two remaining terminals.

In addition, the lead connector 330 may be disposed to overlap the power lead 700 vertically, thereby enhancing current overlap.

That is, since the lead connector 330 and the power lead 700 are disposed to overlap vertically, the current loop may be configured narrowly, thereby increasing the current overlap effect, and as the current overlap increases, the operating efficiency of the power module due to mutual induction can be improved.

A power module, having a structure as described above, can simplify its current loop through the central substrate 300 additionally disposed between the upper substrate 100 and the lower substrate 200.

In addition, the central substrate 300 simplifies the current loop between the upper substrate 100 and the lower substrate 200, thereby enhancing current overlap effect.

Furthermore, an insulating pattern and a via spacer 600 for forming a current loop are reduced in size, resulting in a reduction of the overall module size.

Although the present disclosure has been described and illustrated in conjunction with particular embodiments thereof, it will be apparent to those skilled in the art that various improvements and modifications may be made to the present disclosure without departing from the technical idea of the present disclosure defined by the appended claims.

What is claimed is:

1. A power module comprising:
an upper substrate and a lower substrate vertically spaced apart from each other, and
a central substrate disposed between the upper substrate and the lower substrate,
wherein the central substrate includes multiple conductive parts configured to electrically connect the upper substrate and the lower substrate, and an insulating part configured to insulate each of the conductive parts,
wherein the multiple conductive parts include a first conductive part electrically connected to one of the upper substrate and the lower substrate, a second conductive part electrically connecting the upper substrate and the lower substrate, and a third conductive part electrically connected to a signal lead.

2. The power module of claim 1, further comprising
a semiconductor chip disposed on the lower substrate,
wherein at least one of the first conductive part and the second conductive part is connected to the semiconductor chip.

3. The power module of claim 1, wherein the first conductive part extends in a planar shape to form a current path in a horizontal direction.

4. The power module of claim 1, wherein the first conductive part includes a metal material in a planar shape extending in a horizontal direction to form a current path across an area of the first conductive part.

5. The power module of claim 1, wherein the second conductive part is partitioned from the first conductive part by an insulating part, and extends in a vertical direction to be electrically connected to the upper substrate and the lower substrate.

6. The power module of claim 1, wherein the first conductive part has a planar shape, the second conductive part is disposed on an area of the first conductive part and forms a same plane as the first conductive part, and a periphery of the second conductive part is insulated from the first conductive part by the insulating part.

7. The power module of claim 1, wherein the third conductive part forms a pattern on the insulating part, thereby being electrically blocked from other conductive parts and forming the signal lead.

8. The power module of claim 1, wherein the first conductive part has a planar shape, the insulating part is coated on one surface of the first conductive part, and the third conductive part forms a pattern on an exposed surface of the insulating part.

9. The power module of claim 1, wherein a spacer is coupled to the second conductive part, and the upper substrate and the lower substrate are electrically connected through the second conductive part and the spacer.

10. The power module of claim 9, wherein the spacer includes an upper spacer and a lower spacer, wherein the upper spacer is electrically connected to the upper substrate and the second conductive part, and the lower spacer is electrically connected to the lower substrate and the second conductive part.

11. The power module of claim 1, wherein a through hole is formed in the first conductive part, and the second conductive part has a vertically extending shape and electrically connects the upper substrate and the lower substrate by penetrating the through hole.

12. The power module of claim 1, wherein a power lead is connected to at least one of the upper substrate and the lower substrate, and
a lead connector extends in the central substrate in a direction where the power lead is provided.

13. The power module of claim 12, wherein the lead connector includes or is connected to one of a positive terminal, a negative terminal, and an output terminal, and the power lead includes one of two remaining terminals.

14. The power module of claim 12, wherein the lead connector is spaced apart from the power lead to vertically overlap the power lead.

15. The power module of claim 1, wherein the first conductive part is in a form of a flat plate, and a current path in the first conductive part is formed to vertically overlap the current path in the upper substrate or the lower substrate.
